(19) United States
(12) Patent Application Publication
(10) Pub. No.: US 2017/0170159 A1
(43) Pub. Date: Jun. 15, 2017

(54) SYSTEM AND METHOD FOR IMPROVING DICING QUALITY FOR BONDED WAFER PAIRS

(71) Applicant: INTEGRATED DEVICE TECHNOLOGY, INC., San Jose, CA (US)

(72) Inventors: Srikanth Kulkarni, Freemont, CA (US); Viresh P. Patel, Austin, TX (US)

(73) Assignee: Integrated Device Technology, Inc.

(21) Appl. No.: 14/967,050

(22) Filed: Dec. 11, 2015

(51) Int. Cl. H01L 25/00; H01L 21/78

(52) U.S. Cl. CPC H01L 25/50; H01L 21/78

(57) ABSTRACT

A method for manufacturing a plurality of die pairs includes providing a first wafer including a plurality of spaced apart first dies arranged in a first array including a first, first die row and a second, first die row spaced apart by a first portion of a first row channel; providing a second wafer including a plurality of spaced apart second dies arranged in a second array including a first, second die row and a second, second die row spaced apart by a second portion of the first row channel; connecting the first wafer to the second wafer with a connector assembly to form a wafer pair such that the first dies and the second dies cooperate to form the plurality of die pairs; positioning a first support assembly between the first wafer and the second wafer to rigidly support the first wafer relative to the second wafer; and cutting along the first row channel with a blade to separate the plurality of die pairs from one another.

### BACKGROUND

A wafer is a thin slice of semiconductor material, such as a crystalline silicon, that is commonly used in electronics for the fabrication of integrated circuits or “dies”. Typically, a plurality of dies are fabricated in an array of columns and rows on a single wafer. After fabrication, the individual dies are separated (diced) and packaged. In recent years, there has been a move toward the use of bonded wafer pairs where wafers are bonded one on top of another as a means to increase computing capacity while saving space, i.e. to increase computing density. The wafers utilized to form the bonded wafer pairs are typically each of a similar design with regard to the size and positioning of the individual dies on each wafer, and thus can be utilized to manufacture a plurality of bonded die pairs. In using such bonded wafer pairs to manufacture a plurality of die pairs, it is desired to provide a system and method for dicing the bonded wafer pairs that enhances the quality, integrity and reliability of the individual dies within each die pair.

### SUMMARY

The present invention is directed toward a method for manufacturing a plurality of bonded die pairs comprising (A) providing a first wafer having a plurality of first dies that are arranged in a first array; (B) providing a second wafer having a plurality of second dies that are arranged in a second array; (C) bonding the first wafer to the second wafer to form a bonded wafer pair with a plurality of spaced apart connector members that are arranged in a connector array; wherein each connector member extends between the first wafer and the second wafer, and each connector member extends between one first die and one second die to form a plurality of connected, bonded die pairs; (D) positioning a first support assembly between the first wafer and the second wafer to support the first wafer relative to the second wafer; and (E) cutting the wafers to separate the plurality of connected, bonded die pairs from one another.

With the present method, die pairs can be manufactured from a bonded wafer pair that are of greatly improved quality, integrity and reliability as compared to die pairs formed with previous manufacturing methods. For example, by providing necessary and desired support of the wafers, the wafers are inhibited from deflecting during the cutting process, and are thus much less likely to experience chips or cracks during the dicing process, which may propagate over time, and which can greatly compromise the quality, integrity and reliability of the die pairs.

In some embodiments, bonding includes the connector array including a first connector row and a second connector row that are spaced apart by a first row channel, positioning includes the first support assembly being positioned within and filling the first row channel, and cutting includes cutting along the first row channel to separate the plurality of connected, bonded die pairs from one another.

Additionally, in other embodiments, bonding includes the connector array including a first connector column and a second connector column that are spaced apart by a first column channel, positioning includes the first support assembly being positioned within and filling the first column channel, and cutting includes cutting along the first column channel to separate the plurality of connected, bonded die pairs from one another.

Further, in certain embodiments, bonding includes the connector array including a plurality of connector rows and a plurality of connector columns, wherein adjacent connector rows are separated by a separate row channel and adjacent connector columns are separated by a separate column channel; and positioning includes the first support assembly being positioned within and filling the row channels and the column channels. In some such embodiments, cutting includes cutting along each row channel and each column channel to separate the plurality of connected, bonded die pairs from one another.

Additionally, in some embodiments, providing a first wafer includes the first wafer having a first surface and an opposed second surface, providing a second wafer includes the second wafer having a first surface and an opposed second surface, positioning includes positioning the first support assembly between the second surface of the first wafer and the first surface of the second wafer, and further comprising securing a second support assembly to the second surface of the second wafer. The method can further comprise mounting the bonded wafer pair on a support surface, wherein securing a second support assembly includes the second support assembly stiffly supporting the second wafer relative to the support surface.

Further, in certain embodiments, positioning a first support assembly includes positioning the first support assembly between the first wafer and the second wafer prior to bonding the first wafer to the second wafer with the connector members; and the first support assembly includes a no-flow underfill material.

Still further, bonding the first wafer to the second wafer can include each of the plurality of first dies being hermetically sealed to one of the plurality of second dies. In such embodiments, positioning a first support assembly can include positioning the first support assembly between the first wafer and the second wafer after bonding the first wafer to the second wafer with the connector members; and the first support assembly can include a capillary underfill material that flows between the connector members and between the first wafer and the second wafer.

The present invention is further directed toward a method for manufacturing a plurality of die pairs comprising (A) providing a first wafer having a first surface and an opposed second surface, the first wafer including a plurality of first dies that are arranged in a first array, the first array including (i) a first, first die row and a second, first die row that are positioned substantially adjacent to one another with a first cut line therebetween, and (ii) a first, first die column; (B) providing a second wafer having a first surface and an opposed second surface, the second wafer including a plurality of second dies that are arranged in a second array, the second array including (i) a first, second die row and a second, second die row that are positioned substantially adjacent to one another with a second cut line therebetween, and (ii) a first, second die column; (C) connecting the first wafer to the second wafer with a plurality of spaced apart connector members that are positioned between the second surface of the first wafer and the first surface of the second wafer to form a wafer pair such that each of the plurality of first dies is positioned substantially adjacent to one of the plurality of second dies with a connector member positioned therebetween, the first dies and the second dies cooperating to form the plurality of die pairs; (D) positioning a first support assembly between the second surface of the first wafer and the first surface of the second wafer in a first row channel to stiffly support the first wafer relative to the second wafer, the first cut line, the second cut line and the first row channel being substantially aligned with one another to form a first cutting row channel; and (E) cutting along the first cutting row channel with a blade to separate the plurality of die pairs from one another.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a simplified perspective view illustration of an embodiment of a wafer pair assembly having features of the present invention, the wafer pair assembly including a first wafer and a second wafer that are bonded together with a connector assembly to form a bonded wafer pair;

FIG. 1B is a simplified bottom view illustration of the first wafer illustrated in FIG. 1A;

FIG. 1C is a simplified top view illustration of the second wafer and the connector assembly illustrated in FIG. 1A;

FIG. 1D is a simplified perspective view illustration of the connector assembly illustrated in FIG. 1A;

FIG. 1E is a simplified perspective view illustration of a first support assembly usable as part of the wafer pair assembly of FIG. 1A;

FIG. 1F is a simplified perspective view illustration of a second support assembly usable as part of the wafer pair assembly of FIG. 1A;

FIG. 1G is a simplified top view illustration of the wafer pair assembly of FIG. 1A;

FIG. 1H is a simplified cutaway view of the wafer pair assembly taken on line H-H in FIG. 1G, and a blade that can be utilized for dicing the bonded wafer pair to provide a plurality of die pairs;

FIG. 1I is a simplified cutaway view of the wafer pair assembly taken on line I-I in FIG. 1G, and the blade illustrated in FIG. 1H;

FIG. 2 is a simplified perspective view of a plurality of die pairs manufactured with the wafer pair assembly of FIG. 1A;

FIG. 3 is a flowchart that illustrates an embodiment of a method for manufacturing a plurality of die pairs utilizing the wafer pair assembly of FIG. 1A; and

FIG. 4 is a flowchart that illustrates another embodiment of a method for manufacturing a plurality of die pairs utilizing the wafer pair assembly of FIG. 1A.

### DESCRIPTION

Embodiments of the present invention are described herein in the context of an assembly and method for manufacturing a plurality of die pairs. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

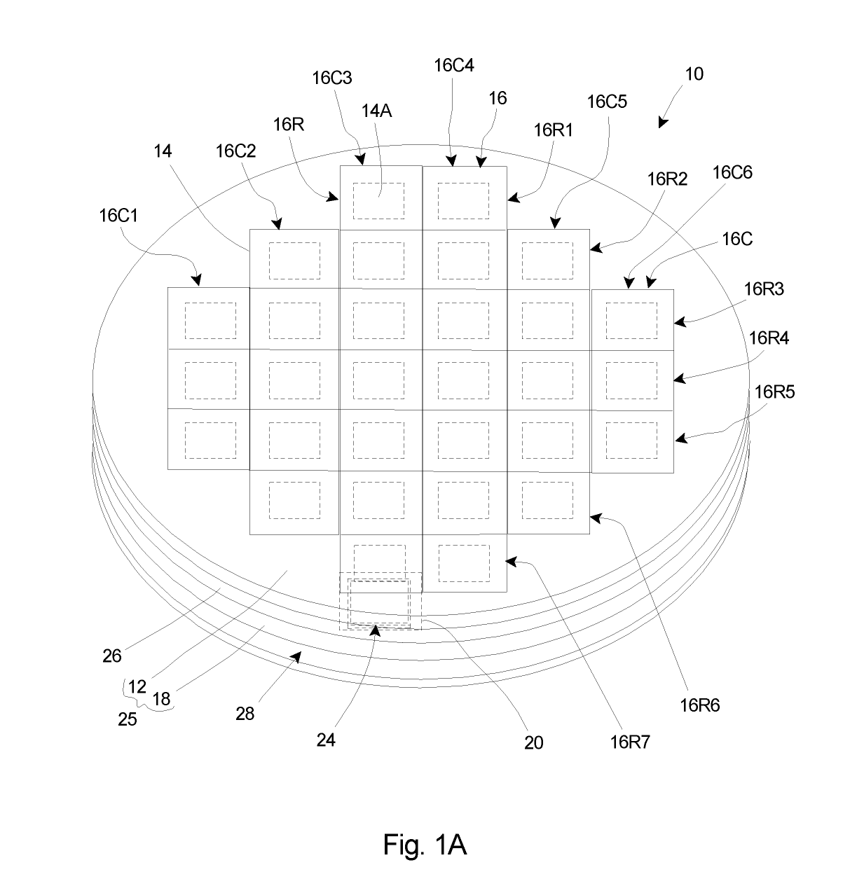

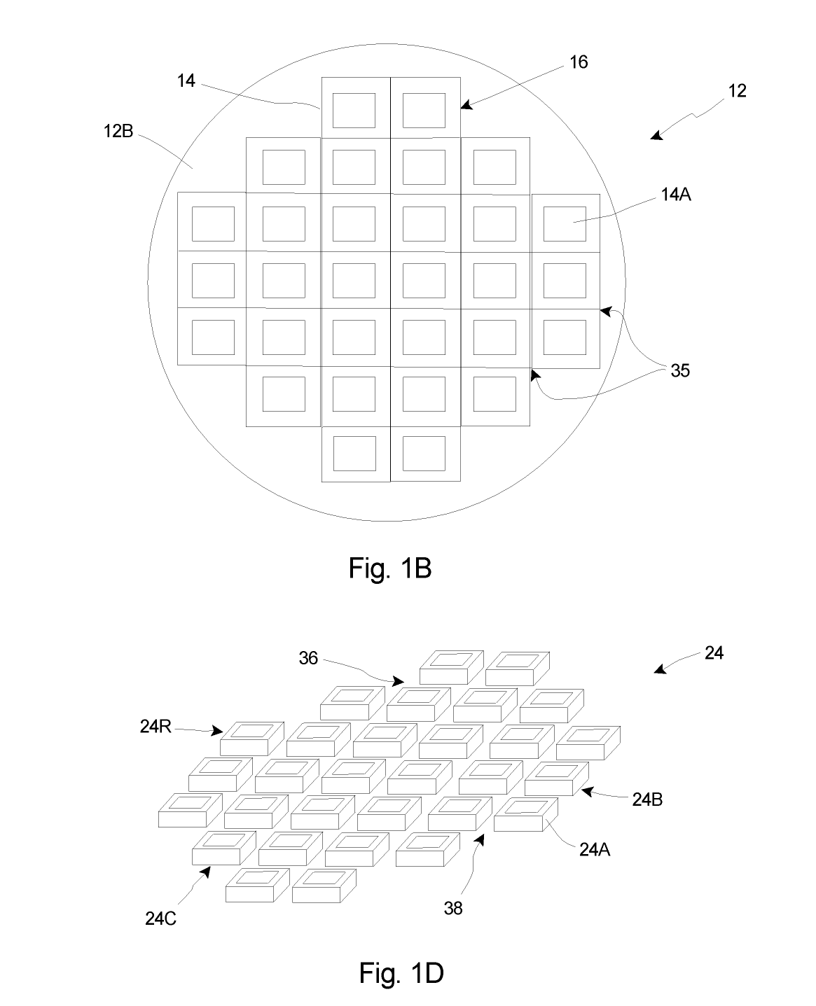

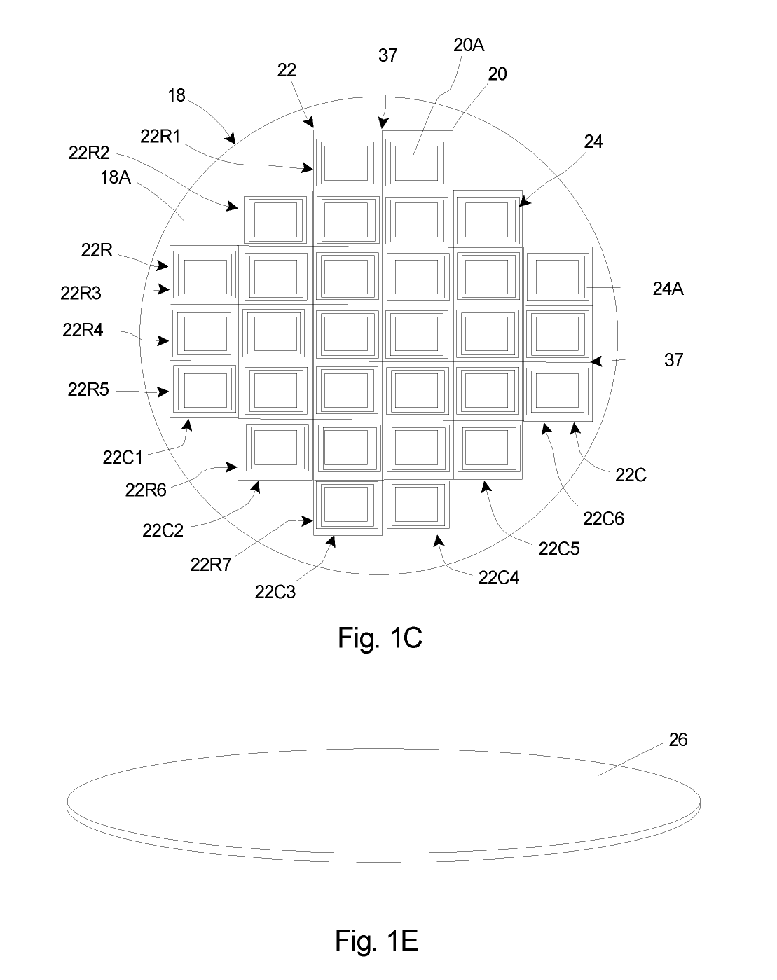

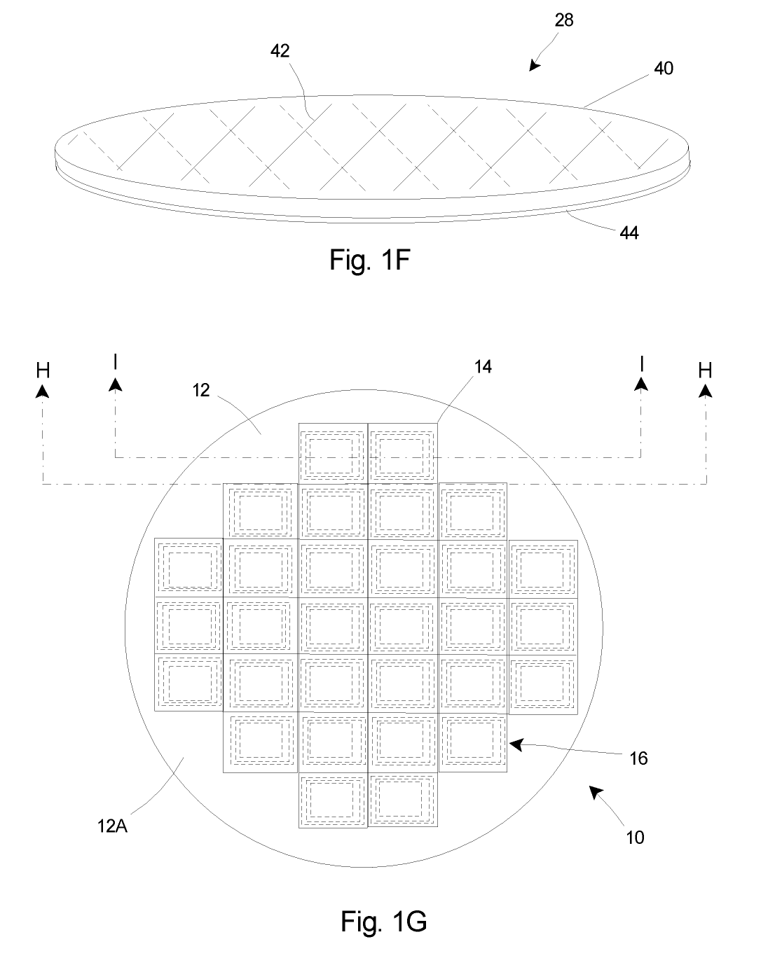

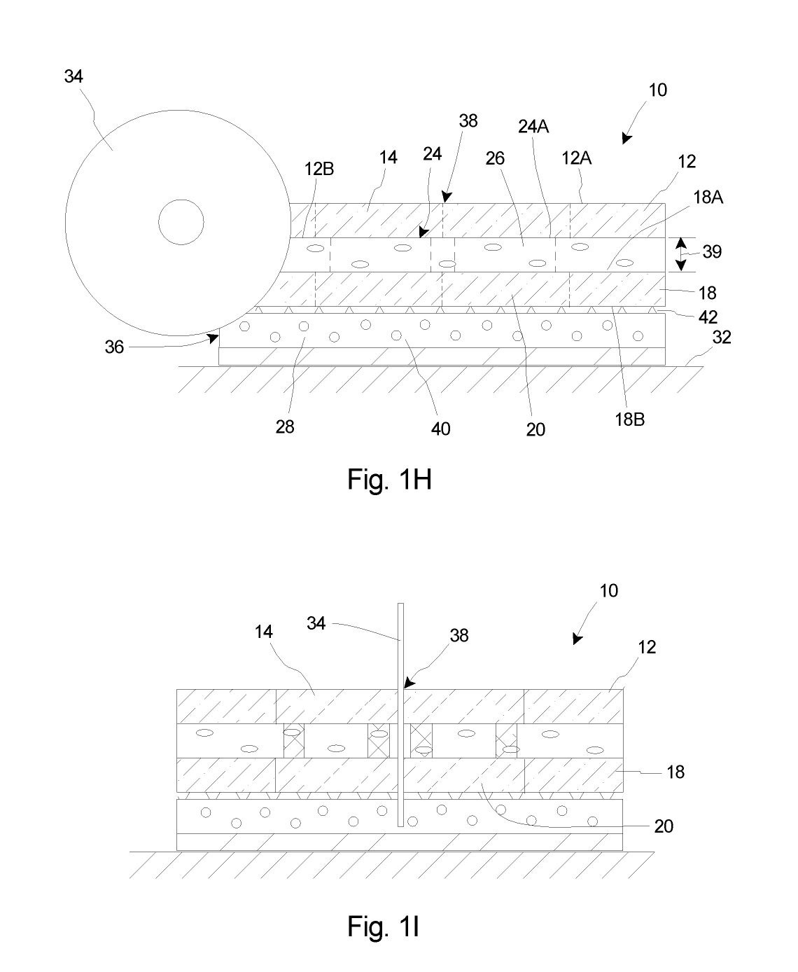

FIG. 1A is a simplified perspective view illustration of an embodiment of a wafer pair assembly 10 having features of the present invention prior to dicing. As provided herein, the design of the wafer pair assembly 10 can be varied. As shown in FIG. 1A, the wafer pair assembly 10 can include (i) a first wafer 12 having a plurality of first dies 14 that are arranged in a first die array 16 (sometimes referred to herein simply as a “first array”), (ii) a second wafer 18 having a plurality of second dies 20 (only a portion of one such second die 20 is illustrated in phantom in FIG. 1A) that are arranged in a second die array 22 (illustrated in FIG. 1E, and sometimes referred to herein simply as a “second array”), (iii) a connector assembly 24 (only a portion is illustrated in phantom in FIG. 1) that connects, i.e. bonds, the first wafer 12 and the second wafer 18 to form a bonded wafer pair 25 with the first wafer 12 spaced apart from the second wafer 18 by a wafer gap 39 (illustrated in FIG. 1H), (iv) a first support assembly 26, and (v) a second support assembly 28. Alternatively, the wafer pair assembly 10 can have a different design. For example, the wafer pair assembly 10 can include more components or fewer components than what is specifically illustrated and described herein.

It should be appreciated that the use of the terms “first” and “second” in relation to the wafers 12, 18, the dies 14, 20, the arrays 16, 22, and the support assemblies 26, 28 is merely for convenience and ease of description, and such labelling is not intended to be limiting in any manner. In particular, either of the wafers 12, 18, the dies 14, 20, the arrays 16, 22, and the support assemblies 26, 28 can be referred to as “first” or “second” without departing from the intended scope and breadth of the present invention.

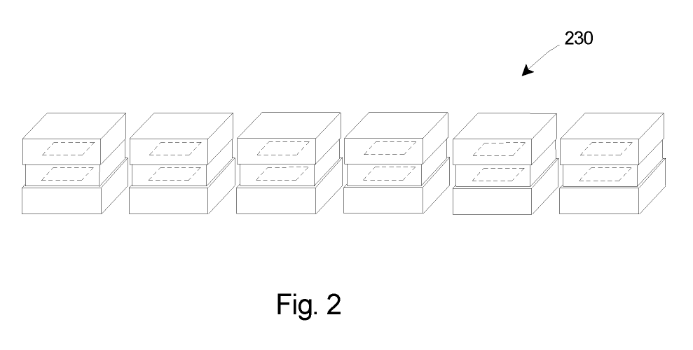

As an overview, the wafer pair assembly 10 as illustrated and described herein enables the manufacturing of a plurality of bonded die pairs 230 (illustrated in FIG. 2) from the bonded wafer pair 25 that are of greatly improved quality, integrity and reliability as compared to bonded die pairs formed with previous assemblies. More specifically, as described in greater detail herein below, the first support assembly 26 provides relatively rigid and/or stiff support for the first wafer 12 relative to the second wafer 18 during the process of separating the plurality of bonded die pairs 230 from one another, i.e. during the dicing process; and the second support assembly 28 provides relatively rigid and/or stiff support for the second wafer 28 relative to a support surface 32 (illustrated, for example, in FIG. 1H) during the dicing process. With such design, the wafers 12, 18 are inhibited from yielding to compressive stress from a blade 34 (illustrated, for example, in FIG. 1H) utilized during the dicing process. Conversely, without the presence of the first support assembly 26 and/or the second support assembly 28, the edges of the first wafer 12 and/or the second wafer 18 may experience chips or cracks during the dicing process, which may propagate over time, and which can greatly compromise the quality, integrity and reliability of the bonded die pairs 230.

Thus, the present invention includes procedures to improve the dicing quality in wafer-to-wafer bonded pairs. In particular, by including an extra process step to improve the mechanical strength and support of the wafers 12, 18 between adjacent dies 14, 20, the wafer dicing quality can be greatly improved. Accordingly, this can also have a direct and positive impact on the manufacturing yield and the product cost.

The design of the first wafer 12 can be varied. For example, as illustrated, the first wafer 12 can be substantially circular disk-shaped and can include the plurality of first dies 14 that are formed on or within the first wafer 12. Alternatively, the first wafer 12 can have a different design, e.g., be formed in a different shape.

Further, the first wafer 12 can be formed from any suitable materials. For example, in various embodiments, the first wafer 12 can be formed from a crystalline silicon material. Alternatively, the first wafer 12 can be formed from another poly crystalline material such as glass. Still alternatively, the first wafer 12 can be formed from other suitable materials.

As shown, the first dies 14 can have a substantially square-shaped cross-section, with a printed area 14A including a set of electronic circuits formed within a smaller square-shaped area along one surface, i.e. a second (bottom or inner) surface 12B (illustrated in FIG. 1B), of the first wafer 12. Alternatively, the first dies 14 can have a substantially rectangle-shaped cross-section or can have another suitable shape.

Additionally, as noted above, the first dies 14 are arranged in the first array 16 on the first wafer 12. In particular, the first array 16 can include one or more first die rows 16R and one or more first die columns 16C. In the specific embodiment illustrated in FIG. 1A, the first wafer 12, i.e. the first array 16, includes seven first die rows 16R, i.e. a first, first die row 16R1, a second, first die row 16R2, a third, first die row 16R3, a fourth, first die row 16R4, a fifth, first die row 16R5, a sixth, first die row 16R6 and a seventh, first die row 16R7; and six first die columns 16C, i.e. a first, first die column 16C1, a second, first die column 16C2, a third, first die column 16C3, a fourth, first die column 16C4, a fifth, first die column 16C5 and a sixth, first die column 16C6. Alternatively, the first array 16 can include greater than seven or fewer than seven first die rows 16R, and/or the first array 16 can include greater than six or fewer than six first die columns 16C.

Further, the number of first dies 14 formed on or within the first wafer 12 can also be varied. In this embodiment, the first wafer 12 includes thirty first dies 14. In particular, as shown, (i) the first, first die row 16R1 includes two first dies 14, (ii) the second, first die row 16R2 includes four first dies 14, (iii) the third, first die row 16R3 includes six first dies 14, (iv) the fourth, first die row 16R4 includes six first dies 14, (v) the fifth, first die row 16R5 includes six first dies 14, (vi) the sixth, first die row 16R6 includes four first dies 14, and (vii) the seventh, first die row 16R7 includes two first dies 14. Additionally, as shown, (i) the first, first die column 16C1 includes three first dies 14, (ii) the second, first die column 16C2 includes five first dies 14, (iii) the third, first die column 16C3 includes seven first dies 14, (iv) the fourth, first die column 16C4 includes seven first dies 14, (v) the fifth, first die column 16C5 includes five first dies 14, and (vi) the sixth, first die column 16C6 includes three first dies 14. Alternatively, the first wafer 12 can include greater than thirty or fewer than thirty first dies 14 and/or the first array 16 can be different than what is specifically shown in FIG. 1A.

FIG. 1B is a simplified bottom view illustration of the first wafer 12 illustrated in FIG. 1A. As illustrated in FIG. 1B, the first wafer 12 includes the plurality of first dies 14 positioned substantially adjacent to one another in the first array 16. Additionally, FIG. 1B also shows the printed area 14A that is formed along the second surface 12B of the first wafer 12 within each die 14.

Additionally, as discussed in greater detail herein below, FIG. 1B also shows a plurality of first cut lines 35 between adjacent first dies 14 and along the outer edges of the first array 16 where the blade 34 (illustrated in FIG. 1H) will be cutting during the dicing process.

FIG. 1C is a simplified top view illustration of the second wafer 18 and the connector assembly 24 illustrated in FIG. 1A. FIG. 1C illustrates various features and aspects of the components of the second wafer 18 and the connector assembly 24 that are not clearly visible in FIG. 1A.

As with the first wafer 12, the design of the second wafer 18 can be varied. In various embodiments, the second wafer 18 can be substantially similar to the first wafer 12.

As illustrated, the second wafer 18 can be substantially circular disk-shaped and can include the plurality of second dies 20 that are formed on or within the second wafer 18. Alternatively, the second wafer 18 can have a different design, e.g., be formed in a different shape.

Further, the second wafer 18 can be formed from any suitable materials. For example, in various embodiments, the second wafer 18 can be formed from a crystalline silicon material. Alternatively, the second wafer 18 can be formed from another poly crystalline material such as glass. Still alternatively, the second wafer 18 can be formed from other suitable materials.

In certain embodiments, the second wafer 18 is formed from the same materials as the first wafer 12. Alternatively, the first wafer 12 and the second wafer 18 can be formed from different materials.

As shown, the second dies 20 can have a substantially square-shaped cross-section, with a printed area 20A including a set of electronic circuits formed within a smaller square-shaped area along one surface, i.e. a first (upper or inner) surface 18A of the second wafer 18. Alternatively, the second dies 20 can have a substantially rectangle-shaped cross-section or can have another suitable shape.

Additionally, as noted above, the second dies 20 are arranged in the second array 22 on the second wafer 18. In various embodiments, as shown, the second array 22 can be substantially similar to, if not identical to, the first array 16. In such embodiments, when the first wafer 12 is connected to the second wafer 18 to form the bonded wafer pair 25 (illustrated in FIG. 1A), each of the plurality of first dies 14 can be positioned substantially adjacent to one of the plurality of second dies 20 as part of forming the plurality of bonded die pairs 230 (illustrated in FIG. 2). For example, in certain embodiments, the second array 22 can include one or more second die rows 22R and one or more second die columns 22C. In the specific embodiment illustrated in FIG. 1C, the second wafer 18, i.e. the second array 22, includes seven second die rows 22R, i.e. a first, second die row 22R1, a second, second die row 22R2, a third, second die row 22R3, a fourth, second die row 22R4, a fifth, second die row 22R5, a sixth, second die row 22R6 and a seventh, second die row 22R7; and six second die columns 22C, i.e. a first, second die column 22C1, a second, second die column 22C2, a third, second die column 22C3, a fourth, second die column 22C4, a fifth, second die column 22C5 and a sixth, second die column 22C6. Alternatively, the second array 22 can include greater than seven or fewer than seven second die rows 22R, and/or the second array 22 can include greater than six or fewer than six second die columns 22C.

Further, the number of second dies 20 formed on or within the second wafer 18 can also be varied. In this embodiment, the second wafer 18 includes thirty second dies 20. In particular, as shown, (i) the first, second die row 22R1 includes two second dies 20, (ii) the second, second die row 22R2 includes four second dies 20, (iii) the third, second die row 22R3 includes six second dies 20, (iv) the fourth, second die row 22R4 includes six second dies 20, (v) the fifth, second die row 22R5 includes six second dies 20, (vi) the sixth, second die row 22R6 includes four second dies 20, and (vii) the seventh, second die row 22R7 includes two second dies 20. Additionally, as shown, (i) the first, second die column 22C1 includes three second dies 20, (ii) the second, second die column 22C2 includes five second dies 20, (iii) the third, second die column 22C3 includes seven second dies 20, (iv) the fourth, second die column 22C4 includes seven second dies 20, (v) the fifth, second die column 22C5 includes five second dies 20, and (vi) the sixth, second die column 22C6 includes three second dies 20. Alternatively, the second wafer 18 can include greater than thirty or fewer than thirty second dies 20 and/or the second array 22 can be different than what is specifically shown in FIG. 1B.

Additionally, as discussed in greater detail herein below, FIG. 1C also shows a plurality of second cut lines 37 between adjacent second dies 20 and along the outer edges of the second array 22 where the blade 34 (illustrated in FIG. 1H) will be cutting during the dicing process.

The connector assembly 24 connects, e.g., bonds, the first wafer 12 to the second wafer 18 to form the bonded wafer pair 25. The design of the connector assembly 24 can be varied. For example, in the embodiment illustrated in FIG. 1C, the connector assembly 24 comprises a plurality of spaced apart connector members 24A. The connector members 24A can be substantially square ring-shaped, and can be positioned to substantially encircle the printed areas 14A, 20A of each of the dies 14, 20 of each individual die pair 230. With such design, the connector members 24A can be utilized such that each first die 14 is bonded to one second die 20 to form the bonded die pairs 230. Alternatively, the connector assembly 24 can have a different design, e.g., the connector members 24A can be formed in another suitable shape.

Referring now to FIG. 1D, this Figure is a simplified perspective view illustration of the connector assembly 24 illustrated in FIG. 1A. FIG. 1D illustrates certain features and aspects of the connector assembly 24, i.e. the connector members 24A, that is not clearly visible in FIG. 1C.

The connector members 24A can be formed from any suitable material. For example, in various embodiments, the connector members 24A can be comprised of a pre-flowed solder material, i.e. a fusible metal alloy, or other suitable braze material. Additionally, in some embodiments, the connector members 24A can be designed to melt at a certain temperature, i.e. a connector melting point, so as to form a seal around each of the individual bonded die pairs 230 (illustrated in FIG. 2). Thus, in some such embodiments, a hermetic seal can be formed around each individual bonded die pair 230. Alternatively, the connector members 24A can be utilized to form a bond between the wafers 12, 18 without providing a hermetic seal around each bonded die pair 230. Still alternatively, the connector assembly 24 can enable bonding between the wafers 12, 18 using other soldering technologies such as transient liquid phase bonding or eutectic bonding. Yet alternatively, other bonding techniques may also be utilized to provide the desired bonding between the first wafer 12 and the second wafer 18.

The size, i.e. the thickness, of the connector assembly 24 can be varied. For example, in various embodiments, the connector assembly 24 can provide a solder interface that can be between approximately two and twenty microns thick in the die 14, 20 area.

Additionally, as shown in FIG. 1D, the connector members 24A are spaced apart from one another in a connector array 24B including a plurality of connector rows 24R and a plurality of connector columns 24C. As shown, the spacing between adjacent connector rows 24R defines a plurality of row channels 36. Somewhat similarly, the spacing between adjacent connector columns 24C defines a plurality of column channels 24C. It should be appreciated that the row channels 36 and the column channels 38 are formed within the wafer gap 39 (illustrated in FIG. 1H), between the wafers 12, 18 (illustrated in FIG. 1A). As such, the wafer gap 39 can be defined as the space between the wafers 12, 18 of the bonded wafer pair 25 represented by the thickness of the connector assembly 24.

It should be appreciated that in the number of row channels 36 and the number of column channels 38 is defined by the number of connector rows 24R and connector columns 24C, respectively, in the connector array 24B. Additionally, since a single connector member 24A is associated with a single first die 14 and a single second die 20, the connector array 24B also corresponds to the first die array 16 and the second die array 22. Thus, the first cut lines 35 (illustrated in FIG. 1B) on the first wafer 12 and the second cut lines 37 (illustrated in FIG. 1C) on the second wafer 18 are substantially aligned with at least a portion of one of the row channels 24R or one of the column channels 24C.

As utilized herein, each row channel 36 along with corresponding first cut lines 35 and second cut lines 37 can be referred to collectively as a “cutting row channel”. Additionally, as utilized herein, each column channel 38 along with corresponding first cut lines 35 and second cut lines 37 can be referred to collectively as a “cutting column channel”.

Additionally, it should be appreciated that the spacing between the connector members 24A and/or the width of the row channels 36 and the column channels 38 have been exaggerated for purposes of clarity and ease of illustration.

FIG. 1E is a simplified perspective view illustration of the first support assembly 26 usable as part of the wafer pair assembly 10 of FIG. 1A. As provided herein, the first support assembly 26 can provide desired support for the first wafer 12 (illustrated in FIG. 1A) relative to the second wafer 18 (illustrated in FIG. 1A) within the wafer gap 39 (illustrated in FIG. 1H) during the dicing process. More particularly, as noted above, the first support assembly 26 provides relatively rigid and/or stiff support for the first wafer 12 relative to the second wafer 18 during the dicing process. Additionally, the first support assembly 26 can have at least a relatively high modulus of elasticity. For example, the first support assembly 26 inhibits the first wafer 12 from deflecting significantly relative to the second wafer 18, or otherwise yielding to compressive stress from the blade 34 (illustrated in FIG. 1H) during the dicing process. Thus, the relatively rigid and/or stiff support provided by the first support assembly 26 inhibits cracks and chips from forming in the first wafer 12 during the dicing process, which could compromise the quality, integrity and reliability of the bonded die pairs 230 (illustrated in FIG. 2).

Yield loss in dicing wafer-to-wafer bonded pairs is very common. This yield loss is more pronounced as the thickness of the interface provided by the connector assembly 24 (illustrated in FIG. 1A), e.g., the solder interface, between the wafers 12, 18 increases. The yield loss is even higher when dicing a poly crystalline material such as glass instead of crystalline silicon. Thus, the rigid or stiff support provided by the first support assembly 26 of the present invention can be even more valuable in special applications where glass wafer pairs with a very thick solder joint are used.

The materials utilized to form the first support assembly 26 can be varied. For example, the first support assembly 26 can use underfill materials having at least a relatively high modulus of elasticity in order to provide the desired rigid or stiff support for the first wafer 12 relative to the second wafer 18 during dicing process. It should be appreciated that the precise modulus of elasticity of the underfill materials used for the first support assembly 26 can vary so long as such underfill materials effectively inhibit the undesired deflection of the first wafer 12 relative to the second wafer 18 during the dicing process. More particularly, in some alternative embodiments, the underfill materials used for the first support assembly 26 can have a high modulus of elasticity or a medium-to-high modulus of elasticity. Alternatively, the first support assembly 26 can utilize other suitable materials.

In some embodiments, the first support assembly 26 can utilize no-flow underfill or wafer level underfill materials in order to achieve the desired support for the first wafer 12 relative to the second wafer 18 during the dicing process. In such embodiments, the underfill materials are applied before the wafer-to-wafer bonding process between the wafers 12, 18. The wafer-to-wafer bonding will require thermocompression bonding since the underfill material interface is required to be displaced for the solder connection to be formed.

It should be appreciated that in some such embodiments, the state of the underfill materials used for the first support assembly 26 can be altered from an initial application state to a supporting state. More specifically, in such embodiments, in the initial application state the underfill materials are less stiff and can be readily moved and formed during the bonding process, e.g., during thermocompression bonding, so as to not interfere with the actual bonding of the wafers 12, 18. Subsequently, after bonding is complete, such underfill materials can harden (or cured) into the desired relatively rigid or stiff supporting state to effectively inhibit undesired deflection of the first wafer 12 relative to the second wafer 18.

In other embodiments, alternative underfill materials may be required. For example, in the specific application where solder is used in the connector assembly 24 to form hermetic seal rings around the bonded die pairs 230, such pre-applied underfill materials are not suitable. This is because the pre-applied underfill material will be trapped inside the seal ring, making it impossible to achieve the desired hermetic seal. In such cases, capillary underfill can be used. In such a process, the underfill material of the first support assembly 26 in its initial application state is a flowing material that is cured and then allowed to seep into row channels 36 (illustrated in FIG. 1D) and column channels 38 (illustrated in FIG. 1D) between adjacent connector members 24A (illustrated in FIG. 1D) of the connector assembly 24. After the capillary underfill process, the areas outside the seal rings i.e., the row channels 36 and column channels 38, are filled with underfill material that can subsequently harden into its supporting state to provide the desired support for the first wafer 12 relative to the second wafer 18.

It should be appreciated that although the first support assembly 26 is illustrated as being substantially circular disk-shaped, the first support assembly 26 can be designed to have any suitable shape that effectively fills the wafer gap 39 between the wafers 12, 18 within the row channels 36 and the column channels 38. Moreover, as provided above, the first support assembly 26 can be formed of a flowing material, and thus may not originate with any definable shape.

FIG. 1F is a simplified perspective view illustration of the second support assembly 28 that is usable as part of the wafer pair assembly 10 of FIG. 1A. The second support assembly 28, as noted above, provides relatively rigid and/or stiff support for the second wafer 18 (illustrated in FIG. 1A) relative to the support surface 32 (illustrated in FIG. 1H) during the dicing process. More particularly, the second support assembly 28 inhibits the second wafer 18 from deflecting relative to the support surface 32, or otherwise yielding to compressive stress from the blade 34 (illustrated in FIG. 1H) during the dicing process. Thus, the rigid or stiff support provided by the second support assembly 28 inhibits cracks and chips from forming in the second wafer 18 during the dicing process, which could compromise the quality, integrity and reliability of the bonded die pairs 230 (illustrated in FIG. 2).

The design of the second support assembly 28 can be varied. For example, in some embodiments, the second support assembly 28 can include a dicing tape 40 that is secured to the second wafer 18 with an adhesive 42 (illustrated with crossed diagonal lines), and a thin metal frame 44 upon which the dicing tape 40 is mounted.

In certain embodiments, the dicing tape 40 can be made of PVC, polyolefin, or polyethylene backing material. Alternatively, the dicing tape 40 can be formed from other suitable materials. For example, in some alternative embodiments, the dicing tape 40 can be formed from an ultraviolet material in which the adhesive bond is broken by exposure to ultraviolet light after dicing. In such embodiments, the adhesive can be stronger during the dicing process, while still allowing for a clean and easily removal of the dicing tape 40 after the dicing process is completed.

In some embodiments, the dicing tape 40 can be provided with a release liner (not shown) that will be removed to reveal the adhesive 42 prior to securing the dicing tape 40 to the second wafer 18.

The dicing tape 40 can be formed in a variety of thicknesses, e.g., from between approximately seventy-five and one hundred fifty microns, and with a variety of adhesive strengths, which are designed for various chip sizes and materials.

In the embodiment illustrated in FIG. 1F, the second support assembly 28, i.e. the dicing tape 40 and the metal frame 44, can be substantially circular disk-shaped to match the general size and shape of the wafers 12, 18. Alternatively, the second support assembly 28 can have a different design. For example, in one non-exclusive alternative embodiment, the second support assembly 28 can have a lattice-like design where the dicing tape 40 is secured to the second wafer 18 only in alignment with the row channels 36 (illustrated in FIG. 1D) and the column channels 38 (illustrated in FIG. 1D).

It should be appreciated that the support provided by the first support assembly 26 and the second support assembly 28 is most critical in alignment with the row channels 36 and the column channels 38 as that is where the blade 34 cuts the wafers 12, 18 during the dicing process.

With the present design, i.e. with use of the first support assembly 26 (the cured underfill material) to support the first wafer 12 relative to the second wafer 18, and with use of the second support assembly 28 (the dicing tape 40 attached to the metal frame 44) to support the second wafer 18 relative to the support surface 32 during the dicing process, the wafer pair assembly 10 is able to manufacture bonded die pairs 230 that are substantially free of chips and cracks that may otherwise compromise the quality, integrity and reliability of the bonded die pairs 230. Thus, the wafer pair assembly 10 of the present invention can greatly improve the dicing quality in wafer-to-wafer bonded pairs, which can also have a direct and positive impact on the manufacturing yield of bonded die pairs 230 and the product cost.

FIG. 1G is a simplified top view illustration of the wafer pair assembly 10 of FIG. 1A. In particular, FIG. 1G provides a view looking straight down upon a first (upper) surface 12A of the first wafer 12. Additionally, FIG. 1G again clearly illustrates the first dies 14 in the first array 16 on the first wafer 12.

FIG. 1H is a simplified cutaway view of the wafer pair assembly 10 taken on line H-H in FIG. 1G. In particular, FIG. 1H more clearly illustrates certain features and aspects as well as the relative positioning of the various components of the wafer pair assembly 10.

As shown in FIG. 1H, the first wafer 12 includes the first (upper) surface 12A and the opposed second (lower or inner) surface 12B; and the second wafer 18 similarly includes the first (upper or inner) surface 18A and an opposed second (lower) surface 18B. During the wafer-to-wafer bonding process, the connector assembly 24 (illustrated in phantom in FIG. 1H), i.e. the plurality of connector members 24A (illustrated in phantom in FIG. 1H), is positioned substantially between the second surface 12B of the first wafer 12 and the first surface 18A of the second wafer 18. In certain embodiments, the connector members 24A are then heated to their melting point so as to effectively form the bond between the second surface 12B of the first wafer 12 and the first surface 18A of the second wafer 18.

Additionally, as illustrated in this embodiment, the first support assembly 26, e.g., the underfill material, is also positioned substantially between the second surface 12B of the first wafer 12 and the first surface 18A of the second wafer 18. As provided herein, the first support assembly 26 is provided at least in the row channels 36 (parallel to the plane of the page) and the column channels 38 (perpendicular to the plane of the page) between the first wafer 12 and the second wafer 18. Thus, the first support assembly 26 can effectively provide the desired rigid or stiff support of the first wafer 12 relative to the second wafer 18 during the dicing process.

Further, as shown, the second support assembly 28, i.e. the dicing tape 40, is secured with the adhesive 42 to the second surface 18B of the second wafer 18. The second support assembly 28 is provided at least in alignment with the row channels 36 and the column channels 38 between the second wafer 18 and the support surface 32 when the bonded wafer pair 25 (illustrated in FIG. 1A) is mounted on the support surface 32 in preparation for dicing. Thus, the second support assembly 28 can effectively provide the desired rigid or stiff support of the second wafer 18 relative to the support surface 32 during the dicing process.

Additionally, FIG. 1H also illustrates the blade 34 that can be utilized to separate the plurality of bonded die pairs 230 (illustrated in FIG. 2) during the dicing process. As shown in FIG. 1H, the blade 34 is positioned along one of the row channels 36. Thus, the blade 34 can provide the desired dicing along the first cut lines 35 (illustrated in FIG. 1B) between adjacent first dies 14 on the first wafer 12, along the second cut lines 37 (illustrated in FIG. 1C) between adjacent second dies 20 on the second wafer 18, as well as along the row channel 36 between adjacent connector members 24A within the wafer gap 39. Such use of the blade 34 effectively dices the bonded wafer pair 25 such that the bonded die pairs 230 (illustrated in FIG. 2) are separated from one another.

FIG. 1I is a simplified cutaway view of the die pair wafer pair assembly 10 taken on line I-I in FIG. 1G, and the blade 34 that can be used during the dicing process. As shown in FIG. 1I, the blade 34 is positioned along one of the column channels 38 (perpendicular to the plane of the page) so as to provide the desired dicing along the first cut lines 35 (illustrated in FIG. 1B) between adjacent first dies 14 on the first wafer 12, along the second cut lines 37 (illustrated in FIG. 1C) between adjacent second dies 20 on the second wafer 18, as well as along the column channel 38 between adjacent connector members 24A within the wafer gap 39. Such use of the blade 34 in the column channels 38 further enables the desired dicing and/or separation of the bonded die pairs 230 (illustrated in FIG. 2).

FIG. 2 is a simplified perspective view of a plurality of die pairs 230 formed with the wafer pair assembly 10 of FIG. 1A. As shown, in this embodiment, each of the die pairs 230 is substantially similar to one another in size and shape. Additionally, due to the use of the wafer pair assembly 10 to form such die pairs 230, the die pairs 230 can be formed substantially free of defects such as cracks and chips that may otherwise be present if utilizing a prior manufacturing assembly. It should be appreciated that in alternative embodiments, one or more of the die pairs 230 can be formed to be a different size and/or shape than any of the other die pairs 230.

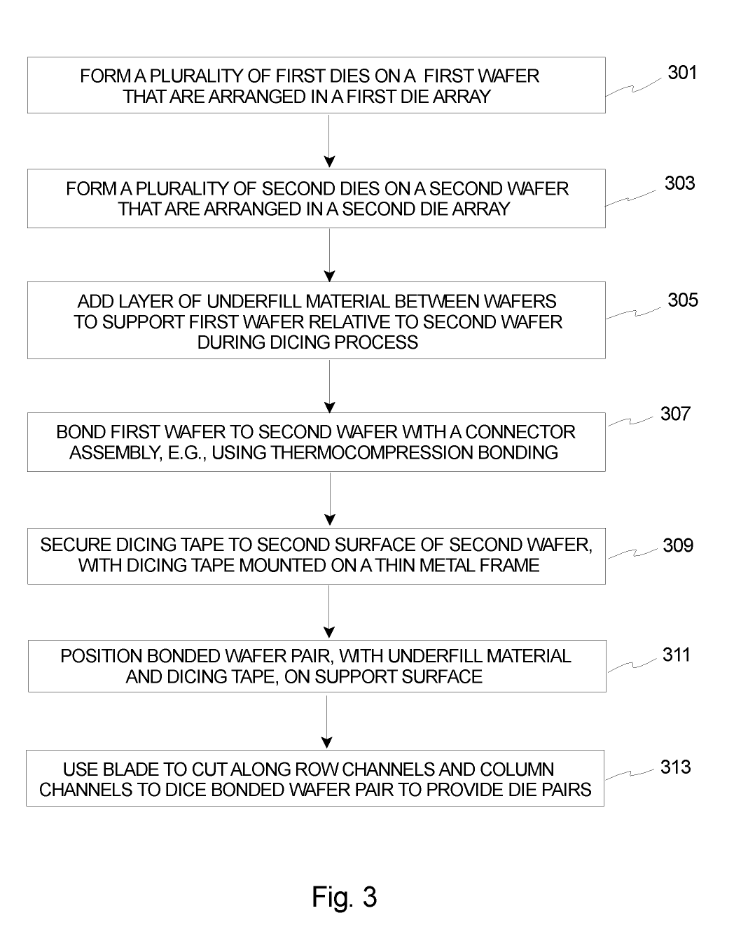

FIG. 3 is a flowchart that illustrates an embodiment of a method for manufacturing a plurality of die pairs utilizing the wafer pair assembly of FIG. 1A.

It should be appreciated that the various steps described herein can be modified as necessary in the process of manufacturing the plurality of die pairs. Additionally, it should also be appreciated that in certain applications the order of the steps can be modified, certain steps can be omitted, and/or additional steps can be added without limiting the intended scope and breadth of the present invention.

In step 301, a plurality first dies are formed on a first wafer. The first dies are arranged on the first wafer in a first die array including one or more first die rows and one or more first die columns. Somewhat similarly, in step 303, a plurality of second dies are formed on a second wafer. The second dies are arranged on the second wafer in a second die array including one or more second die rows and one or more second die columns. In various embodiments, the second die array can be substantially similar to, if not identical to, the first die array.

In step 305, a first support assembly, e.g., a layer of underfill material, is added that is positioned between a second (lower) surface of the first wafer and a first (upper) surface of the second wafer. The first support assembly is thus positioned to provide the desired relatively rigid and/or stiff support for the first wafer relative to the second wafer. In certain embodiments, a no-flow underfill or wafer level underfill materials can be utilized in this step.

In step 307, the first wafer is bonded to the second wafer with a connector assembly to form a bonded wafer pair. The connector assembly can include a plurality of connector members that are formed from a pre-flowed solder material or other suitable braze material. In one embodiment, the bonding between the wafers is formed using thermocompression bonding since the underfill material interface should be displaced for the desired solder-based bonding connection to be formed.

In step 309, a second support assembly is secured via an adhesive to a second (lower) surface of the second wafer. The second support assembly can include a dicing tape that is mounted on a thin metal frame. The second support assembly is thus positioned to provide the desired rigid or stiff support for the second wafer.

In step 311, the bonded wafer pair, with the first support assembly and the second support assembly positioned as described above, is positioned on a support surface.

Finally, in step 313, a blade is used to cut along row channels and column channels between adjacent dies on each wafer. The blade thus functions to dice the bonded wafer pair to provide a plurality of (bonded) die pairs.

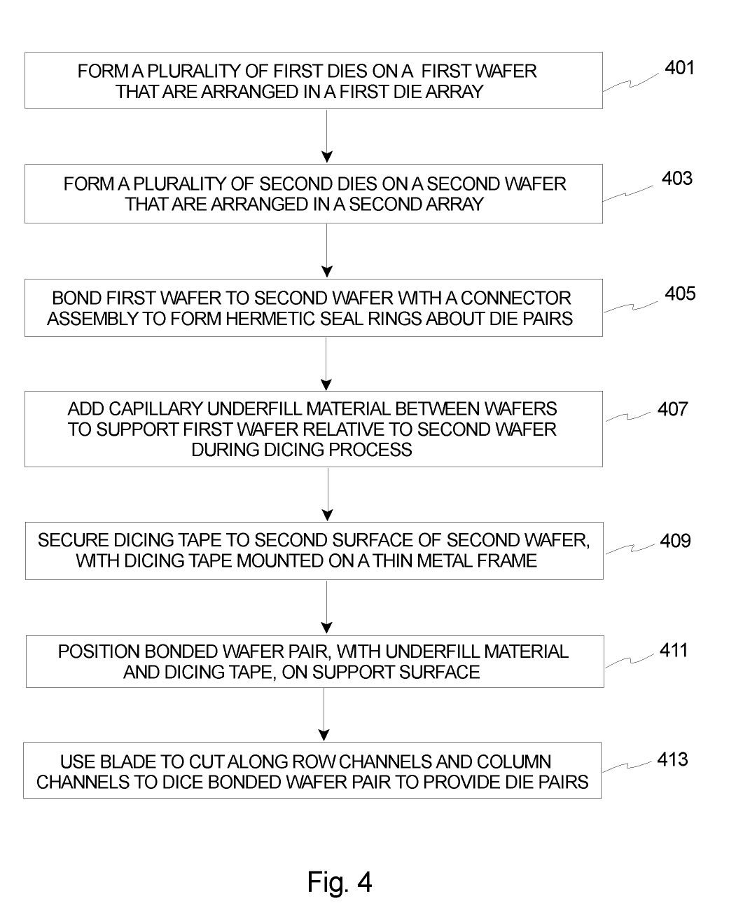

FIG. 4 is a flowchart that illustrates another embodiment of a method for manufacturing a plurality of die pairs utilizing the wafer pair assembly of FIG. 1A.

In step 401, a plurality of first dies are formed on a first wafer. The first dies are arranged on the first wafer in a first die array including one or more first die rows and one or more first die columns. Somewhat similarly, in step 403, a plurality of second dies are formed on a second wafer. The second dies are arranged on the second wafer in a second die array including one or more second die rows and one or more second die columns. In various embodiments, the second die array can be substantially similar to, if not identical to, the first die array.

In step 405, the first wafer is bonded to the second wafer with a connector assembly to form a bonded wafer pair. The connector assembly can include a plurality of connector members that are formed from a pre-flowed solder material or other suitable braze material. In this embodiment, the connector members are sized and shaped so as to form a plurality of seal rings, with each seal ring substantially encircling the printed areas of each die of one die pair, i.e. where one first die that is being bonded to a corresponding single second die.

In step 407, a first support assembly is provided between a second (lower) surface of the first wafer and a first (upper) surface of the second wafer in the form of capillary underfill material. The capillary underfill material can be formed of a flowing material that is cured and then allowed to seep into row channels and column channels between adjacent connector members within a wafer gap between the wafers. The first support assembly is thus positioned to provide the desired relatively rigid and/or stiff support for the first wafer relative to the second wafer.

In step 409, a second support assembly is secured via an adhesive to a second (lower) surface of the second wafer. The second support assembly can include a dicing tape that is mounted on a thin metal frame. The second support assembly is thus positioned to provide the desired rigid or stiff support for the second wafer.

In step 411, the bonded wafer pair, with the first support assembly and the second support assembly positioned as described above, is positioned on a support surface.

Finally, in step 413, a blade is used to cut along row channels and column channels between adjacent dies on each wafer. The blade thus functions to dice the bonded wafer pair to provide a plurality of (bonded) die pairs.

It is understood that although a number of different embodiments of the wafer pair assembly 10 have been illustrated and described herein, one or more features of any one embodiment can be combined with one or more features of one or more of the other embodiments, provided that such combination satisfies the intent of the present invention.

While a number of exemplary aspects and embodiments of a wafer pair assembly 10 have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A method for manufacturing a plurality of bonded die pairs comprising:
providing a first wafer having a plurality of first dies that are arranged in a first array;
providing a second wafer having a plurality of second dies that are arranged in a second array;
bonding the first wafer to the second wafer to form a bonded wafer pair with a plurality of spaced apart connector members that are arranged in a connector array; wherein each connector member extends between the first wafer and the second wafer, and each connector member extends between one first die and one second die to form a plurality of connected, bonded die pairs;
positioning a first support assembly between the first wafer and the second wafer to support the first wafer relative to the second wafer; and
cutting the wafers to separate the plurality of connected, bonded die pairs from one another.

2. The method of claim 1 wherein bonding includes the connector array including a first connector row and a second connector row that are spaced apart by a first row channel, wherein positioning includes the first support assembly being positioned within and filling the first row channel, and wherein cutting includes cutting along the first row channel to separate the plurality of connected, bonded die pairs from one another.

3. The method of claim 1 wherein bonding includes the connector array including a first connector column and a second connector column that are spaced apart by a first column channel, wherein positioning includes the first support assembly being positioned within and filling the first column channel, and wherein cutting includes cutting along the first column channel to separate the plurality of connected, bonded die pairs from one another.

4. The method of claim 1 wherein bonding includes the connector array including a plurality of connector rows and a plurality of connector columns, wherein adjacent connector rows are separated by a separate row channel and adjacent connector columns are separated by a separate column channel; and wherein positioning includes the first support assembly being positioned within and filling the row channels and the column channels.

5. The method of claim 4 wherein cutting includes cutting along each row channel and each column channel to separate the plurality of connected, bonded die pairs from one another.

6. The method of claim 1 wherein providing a first wafer includes the first wafer having a first surface and an opposed second surface, wherein providing a second wafer includes the second wafer having a first surface and an opposed second surface, wherein positioning includes positioning the first support assembly between the second surface of the first wafer and the first surface of the second wafer, and further comprising securing a second support assembly to the second surface of the second wafer.

7. The method of claim 6 further comprising mounting the bonded wafer pair on a support surface, wherein securing a second support assembly includes the second support assembly stiffly supporting the second wafer relative to the support surface.

8. The method of claim 1 wherein positioning a first support assembly includes positioning the first support assembly between the first wafer and the second wafer prior to bonding the first wafer to the second wafer with the connector members; and wherein the first support assembly includes a no-flow underfill material.

9. The method of claim 1 wherein bonding the first wafer to the second wafer includes each of the plurality of first dies being hermetically sealed to one of the plurality of second dies.

10. The method of claim 9 wherein positioning a first support assembly includes positioning the first support assembly between the first wafer and the second wafer after bonding the first wafer to the second wafer with the connector members; and wherein the first support assembly includes a capillary underfill material that flows between the connector members and between the first wafer and the second wafer.

11. A method for manufacturing a plurality of die pairs comprising:
providing a first wafer having a first surface and an opposed second surface, the first wafer including a plurality of first dies that are arranged in a first array, the first array including (i) a first, first die row and a second, first die row that are positioned substantially adjacent to one another with a first cut line therebetween, and (ii) a first, first die column;
providing a second wafer having a first surface and an opposed second surface, the second wafer including a plurality of second dies that are arranged in a second array, the second array including (i) a first, second die row and a second, second die row that are positioned substantially adjacent to one another with a second cut line therebetween, and (ii) a first, second die column;
connecting the first wafer to the second wafer with a plurality of spaced apart connector members that are positioned between the second surface of the first wafer and the first surface of the second wafer to form a wafer pair such that each of the plurality of first dies is positioned substantially adjacent to one of the plurality of second dies with a connector member positioned therebetween, the first dies and the second dies cooperating to form the plurality of die pairs;
positioning a first support assembly between the second surface of the first wafer and the first surface of the second wafer in a first row channel to stiffly support the first wafer relative to the second wafer, the first cut line, the second cut line and the first row channel being substantially aligned with one another to form a first cutting row channel; and
cutting along the first cutting row channel with a blade to separate the plurality of die pairs from one another.

12. The method of claim 11 wherein connecting includes the first wafer being spaced apart from the second wafer by a wafer gap, and wherein positioning a first support assembly includes positioning underfill material in the wafer gap within the first row channel.

13. The method of claim 11 further comprising securing a second support assembly to the second surface of the second wafer.

14. The method of claim 13 further comprising mounting the wafer pair on a support surface, wherein securing a second support assembly includes the second support assembly stiffly supporting the second wafer relative to the support surface.

15. The method of claim 11 wherein providing a first wafer includes the first array including a second, first die column that is substantially adjacent to the first, first die column with a second, first cut line therebetween; wherein providing a second wafer includes the second array including a second, second die column that is substantially adjacent to the first, second die column with a second, second cut line therebetween; wherein positioning includes positioning the first support assembly between the second surface of the first wafer and the first surface of the second wafer in a first column channel to stiffly support the first wafer relative to the second wafer, and wherein cutting includes cutting along the first column channel with the blade to separate the plurality of die pairs from one another.

16. The method of claim 11 wherein providing a first wafer includes each first die including a first printed area, wherein providing a second wafer includes each second die including a second printed area, and wherein connecting includes the connector assembly including a plurality of connector members, each connector member being positioned to substantially encircle one of the first printed areas and one of the second printed areas.

17. The method of claim 11 wherein positioning a first support assembly includes positioning the first support assembly between the second surface of the first wafer and the first surface of the second wafer prior to connecting the first wafer to the second wafer with the connector assembly; and wherein the first support assembly includes a no-flow underfill material.

18. The method of claim 11 wherein connecting the first wafer to the second wafer includes each of the plurality of first dies being hermetically sealed to one of the plurality of second dies.

19. The method of claim 18 wherein positioning a first support assembly includes positioning the first support assembly between the second surface of the first wafer and the first surface of the second wafer after connecting the first wafer to the second wafer with the connector assembly; and wherein the first support assembly includes a capillary underfill material that flows into the first row channel within a wafer gap between the first wafer and the second wafer.

20. The method of claim 11 wherein providing a first wafer includes the first array including a plurality of first die rows, with each pair of adjacent first die rows being connected by a first, first cut line, and a plurality of first die columns, with each pair of first die columns being connected by a second, first cut line.

21. The method of claim 20 wherein providing a second wafer includes the second array including a plurality of second die rows, with each pair of adjacent second die rows being connected by a first, second cut line, and a plurality of second die columns, with each pair of second die columns being connected by a second, second cut line.

22. The method of claim 21 wherein connecting the first wafer to the second wafer includes the connector members comprising a connector array having a plurality of connector rows that are spaced apart by row channels and a plurality of connector columns that are spaced apart by column channels, the first, first cut lines, the first, second cut lines and the row channels being substantially aligned with one another to form a plurality of cutting row channels, and the second, first cut lines, the second, second cut lines and the column channels being substantially aligned with one another to form a plurality of cutting column channels.

23. The method of claim 22 wherein cutting includes cutting along each of the cutting row channels and each of the cutting column channels with the blade to separate the plurality of die pairs from one another.
